(19) United States
(12) Patent Application Publication
(10) Pub. No.: US 2025/0054875 A1
(43) Pub. Date: Feb. 13, 2025

(54) SEMICONDUCTOR DEVICE AND MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: MASASHI UECHA, Nisshin-shi (JP); YUJI NAGUMO, Nisshin-shi (JP); TAKAYA SHIMONO, Nisshin-shi (JP)

(21) Appl. No.: 18/680,085

(22) Filed: May 31, 2024

(30) Foreign Application Priority Data
Aug. 9, 2023 (JP) 2023-129927

(51) Int. Cl. H01L 23/544; H01L 21/683; H01L 21/82; H01L 29/16; H01L 29/66

(52) U.S. Cl. CPC H01L 23/544; H01L 21/6836; H01L 21/8213; H01L 29/1608; H01L 29/66068; H01L 2223/5446

(57) ABSTRACT

A semiconductor device includes a semiconductor substrate having first and second main surfaces, first and second side surfaces opposite to each other in a first direction, and third and fourth side surfaces opposite to each other in a second direction perpendicular to the first direction, and a pattern structure disposed on the first main surface. The pattern structure within a first predetermined distance from the first side surface along the first direction and the pattern structure within the first predetermined distance from the second side surface along the first direction are symmetrical with respect to a line extending in the second direction. The pattern structure within a second predetermined distance from the third side surface along the second direction and the pattern structure within the second predetermined distance from the fourth side surface along the second direction are symmetrical with respect to a line extending in the first direction.

### CROSS REFERENCE TO RELATED APPLICATION

The present application claims the benefit of priority from Japanese Patent Application No. 2023-129927 filed on Aug. 9, 2023. The entire disclosure of the above application is incorporated herein by reference.

### TECHNICAL FIELD

The present disclosure relates to a semiconductor device and a manufacturing method of a semiconductor device.

### BACKGROUND

A manufacturing method of a semiconductor device includes a process of dividing a semiconductor wafer, on which a plurality of element regions is arranged in a matrix form, into individual element regions. In the dividing process, a scribing and breaking method can be adopted. The scribing and breaking method is a method in which weakened portions are formed along boundaries between adjacent element regions, and then a dividing member is pressed along the boundaries to divide the semiconductor wafer. In the scribing and breaking method, the semiconductor wafer is divided by cleaving starting from the weakened portions. Therefore, the scribing and breaking method is also effective for relatively hard materials. Furthermore, since the scribing and breaking method can narrow scribe lines, the number of semiconductor devices that can be produced from the semiconductor wafer can be increased, and a manufacturing cost can be reduced.

### SUMMARY

A semiconductor device according to an aspect of the present disclosure includes a semiconductor substrate and a pattern structure. The semiconductor substrate has a first main surface, a second main surface opposite to the first main surface, and a side surface extending between the first main surface and the second main surface. The side surface is a cleavage plane and includes a first side surface and a second side surface opposite to each other in a first direction parallel to the first main surface and the second main surface, and a third side surface and a fourth side surface opposite to each other in a second direction parallel to the first main surface and the second main surface and perpendicular to the first direction. The pattern structure has a protruding shape and is disposed on the first main surface of the semiconductor substrate. The pattern structure within a first predetermined distance from the first side surface along the first direction and the pattern structure within the first predetermined distance from the second side surface along the first direction are symmetrical with respect to a line extending in the second direction. The pattern structure within a second predetermined distance from the third side surface along the second direction and the pattern structure within the second predetermined distance from the fourth side surface along the second direction are symmetrical with respect to a line extending in the first direction.

A manufacturing method of a semiconductor device according to another aspect includes: forming a pattern structure having a protruding shape on a first main surface of a semiconductor wafer that has the first main surface and a second main surface opposite to the first main surface, the forming of the pattern structure including forming the pattern structure in each of a plurality of element regions arranged in a matrix form in the semiconductor wafer; and dividing the semiconductor wafer along a plurality of first scribe lines extending in a first direction parallel to the first main surface and the second main surface, and a plurality of second scribe lines extending in a second direction parallel to the first main surface and the second main surface and perpendicular to the first direction by pressing a dividing member against the plurality of first scribe lines and the plurality of second scribe lines to divide the semiconductor wafer into a plurality of semiconductor devices. Each of the plurality of semiconductor devices includes a semiconductor substrate having a side surface extending between the first main surface and the second main surface. The side surface includes a first side surface and a second side surface opposed to each other in the first direction, and a third side surface and a fourth side surface opposed to each other in the second direction. The pattern structure within a first predetermined distance from the first side surface along the first direction and the pattern structure within the first predetermined distance from the second side surface along the first direction are symmetrical with respect to a line extending in the second direction. The pattern structure within a second predetermined distance from the third side surface along the second direction and the pattern structure within the second predetermined distance from the fourth side surface along the second direction are symmetrical with respect to a line extending in the first direction.

### BRIEF DESCRIPTION OF DRAWINGS

Objects, features and advantages of the present disclosure will become apparent from the following detailed description made with reference to the accompanying drawings. In the drawings:

FIG. 1 is a plan view schematically showing a layout of a semiconductor wafer;

FIG. 2A is a cross-sectional view showing a schematic pattern structure of the semiconductor wafer and including element regions adjacent in an x-axis direction;

FIG. 2B is a cross-sectional view showing a schematic pattern structure of the semiconductor wafer and including element regions adjacent in a y-axis direction;

FIG. 3 is an enlarged plan view showing a schematic layout of four element regions;

FIG. 4 is a plan view showing a schematic layout of an individual semiconductor device;

FIG. 5 is a plan view showing a schematic layout of an individual semiconductor device;

FIG. 6 is a diagram for explaining a protective tape attaching process;

FIG. 7 is a diagram for explaining a crack forming process;

FIG. 8 is a diagram for explaining a dividing process;

FIG. 9 is a diagram for explaining the dividing process;

FIG. 10 is a diagram for explaining the dividing process; and

FIG. 11 is a diagram for explaining a dividing process according to a comparative example.

### DETAILED DESCRIPTION

In a scribing and breaking method, when a dividing member is pressed against a semiconductor wafer to divide the semiconductor wafer into individual pieces, a phenomenon called chipping may occur, in which a part of a chip breaks off.

A semiconductor device according to an aspect of the present disclosure includes a semiconductor substrate and a pattern structure. The semiconductor substrate has a first main surface, a second main surface opposite to the first main surface, and a side surface extending between the first main surface and the second main surface. The side surface is a cleavage plane and includes a first side surface and a second side surface opposite to each other in a first direction parallel to the first main surface and the second main surface, and a third side surface and a fourth side surface opposite to each other in a second direction parallel to the first main surface and the second main surface and perpendicular to the first direction. The pattern structure has a protruding shape and is disposed on the first main surface of the semiconductor substrate. The pattern structure within a first predetermined distance from the first side surface along the first direction and the pattern structure within the first predetermined distance from the second side surface along the first direction are symmetrical with respect to a line extending in the second direction. The pattern structure within a second predetermined distance from the third side surface along the second direction and the pattern structure within the second predetermined distance from the fourth side surface along the second direction are symmetrical with respect to a line extending in the first direction. This semiconductor device has a structure that can restrict the occurrence of chipping when the semiconductor wafer is divided into individual pieces.

A manufacturing method of a semiconductor device according to another aspect includes: forming a pattern structure having a protruding shape on a first main surface of a semiconductor wafer that has the first main surface and a second main surface opposite to the first main surface, the forming of the pattern structure including forming the pattern structure in each of a plurality of element regions arranged in a matrix form in the semiconductor wafer; and dividing the semiconductor wafer along a plurality of first scribe lines extending in a first direction parallel to the first main surface and the second main surface, and a plurality of second scribe lines extending in a second direction parallel to the first main surface and the second main surface and perpendicular to the first direction by pressing a dividing member against the plurality of first scribe lines and the plurality of second scribe lines to divide the semiconductor wafer into a plurality of semiconductor devices. Each of the plurality of semiconductor devices includes a semiconductor substrate having a side surface extending between the first main surface and the second main surface. The side surface includes a first side surface and a second side surface opposed to each other in the first direction, and a third side surface and a fourth side surface opposed to each other in the second direction. The pattern structure within a first predetermined distance from the first side surface along the first direction and the pattern structure within the first predetermined distance from the second side surface along the first direction are symmetrical with respect to a line extending in the second direction. The pattern structure within a second predetermined distance from the third side surface along the second direction and the pattern structure within the second predetermined distance from the fourth side surface along the second direction are symmetrical with respect to a line extending in the first direction. In this manufacturing method of the semiconductor device, since a uniform load is applied to each of the adjacent element regions during the dividing of the semiconductor wafer, the occurrence of chipping can be restricted.

The following describes embodiments of the present disclosure with reference to the accompanying drawings. For purposes of clarity, only some of repeating structures in the drawings are assigned with reference numerals. In the following, the structures of the semiconductor wafer and the semiconductor device will be described using mutually orthogonal xyz coordinates. An x-axis and a y-axis extend parallel to main surfaces of the semiconductor wafer and a semiconductor substrate of the semiconductor device, and a z-axis extends parallel to a thickness direction of the semiconductor wafer and the semiconductor substrate of the semiconductor device.

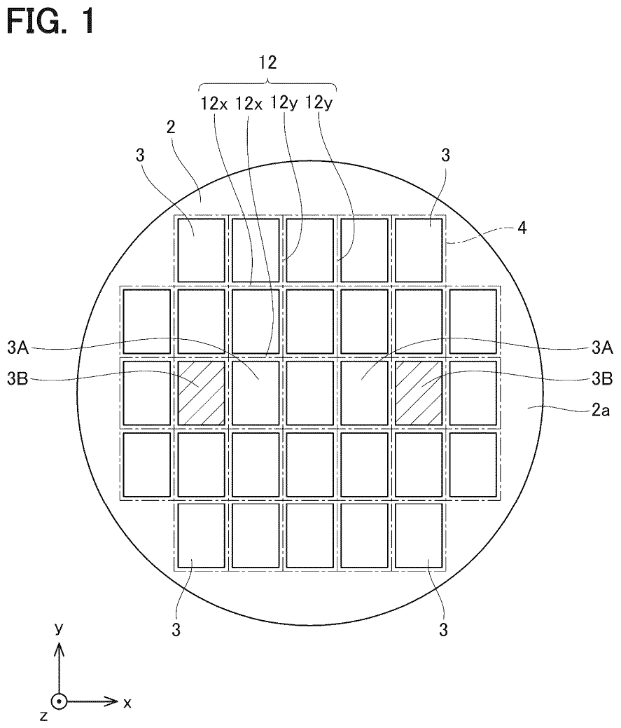

FIG. 1 is a plan view schematically showing a layout of a semiconductor wafer 2. The material of the semiconductor wafer 2 is not particularly limited, but may be, for example, silicon carbide, a nitride semiconductor, or silicon. In this example, the material of the semiconductor wafer 2 is silicon carbide. In the semiconductor wafer 2, a plurality of element regions 3 is arranged in a matrix form. The plurality of element regions 3 includes a plurality of actual element regions 3A which is not hatched in FIG. 1, and a plurality of test element regions 3B (also referred to as “test element group (TEG) regions” which is hatched in FIG. 1.

The actual element region 3A is a region where an element structure is formed, and is a region that becomes the semiconductor device after the semiconductor wafer 2 is divided into individual pieces. The element structure formed in the actual element region 3A is not particularly limited, but may be, for example, a metal oxide semiconductor field effect transistor (MOSFET), an insulated gate bipolar transistor (IGBT), or a diode. In this example, the element structure formed in the actual element region 3A is a MOSFET.

The test element region 3B is a region in which a test pattern is formed. The test pattern in the test element region 3B is not particularly limited, but may be, for example, a test pattern for evaluating a process when forming the element structure in the actual element region 3A, or a test pattern for evaluating electrical characteristics of the element structure in the actual element region 3A. The test element region 3B is appropriately formed in the semiconductor wafer 2 depending on the purpose.

The element regions 3 are partitioned by a plurality of scribe lines 12. The plurality of scribe lines 12 include a plurality of first scribe lines 12x extending in the x-axis direction and a plurality of second scribe lines 12y extending in the y-axis direction. The first scribe lines 12x are arranged at intervals from one another in the y-axis direction. The second scribe lines 12y are arranged at intervals from one another in the x-axis direction. The scribe lines 12 include planned dividing lines 4 along which the semiconductor wafer 2 is divided. The planned dividing lines 4 are not actually drawn on the semiconductor wafer 2 but are virtual lines.

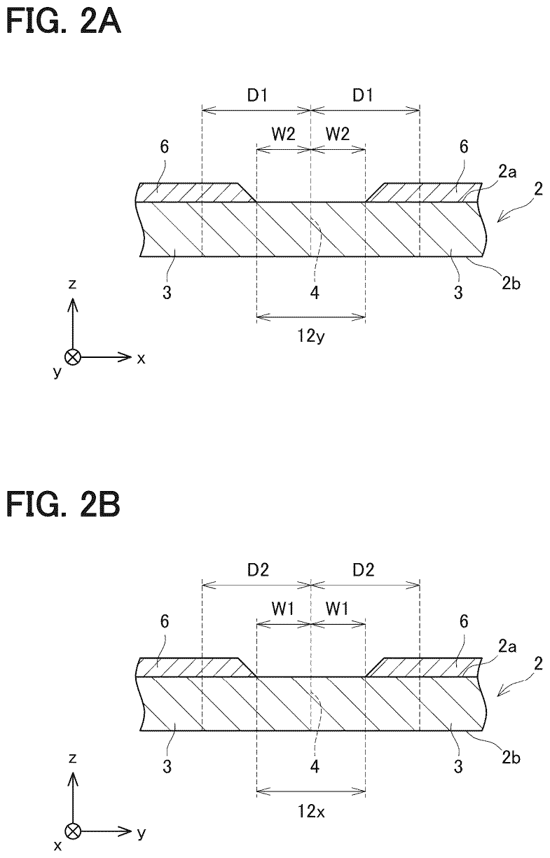

FIG. 2A and FIG. 2B are schematic cross-sectional views of the semiconductor wafer 2 including adjacent element regions 3. FIG. 2A is a cross-sectional view of the semiconductor wafer 2 including the element regions 3 adjacent to each other in the x-axis direction, and FIG. 2B is a cross-sectional view of the semiconductor wafer 2 including the element regions 3 adjacent to each other in the y-axis direction. The element regions 3 shown in FIG. 2A and FIG. 2B may be either the actual element region 3A or the test element region 3B. In other words, the cross-sectional view of FIG. 2A shows the cross-sectional view including any element regions 3 adjacent to each other in the x-axis direction within the semiconductor wafer 2, and the cross-sectional view of FIG. 2B shows the cross-sectional view including any element regions 3 adjacent to each other in the y-axis direction within the semiconductor wafer 2. As shown in FIG. 2A and FIG. 2B, the semiconductor wafer 2 includes a first main surface 2a and a second main surface 2b extending parallel to the xy plane and facing each other in the z-axis direction. A protruding pattern structure 6 that protrudes from the first main surface 2a of the semiconductor wafer 2 is disposed in each of the element regions 3. When the element region 3 is the actual element region 3A, the pattern structure 6 disposed in the actual element region 3A is a pattern of a protective film of an insulator (polyimide in this example), a metal electrode, and the like that constitute the element structure. The pattern structures 6 respectively disposed in the actual element regions 3A have a common shape among the plurality of actual element regions 3A. When the element region 3 is the test element region 3B, the pattern structure 6 disposed in the test element region 3B is a pattern of a protective film of an insulator (polyimide in this example), a metal electrode, and the like formed as the test pattern.

The scribe lines 12 are defined as areas between the adjacent element regions 3 where no pattern structure 6 is disposed. As shown in FIG. 2A, the width of the second scribe line 12y is 2×W2, and the width of the second scribe lines 12 in each of the element regions 3 is W2. As shown in FIG. 2B, the width of the first scribe lines 12x is 2×W1, and the width of the first scribe lines 12x in each of the element region 3 is W1. The width W1 of the first scribe lines 12x and the width W2 of the second scribe lines 12y may be the same size or may be different sizes.

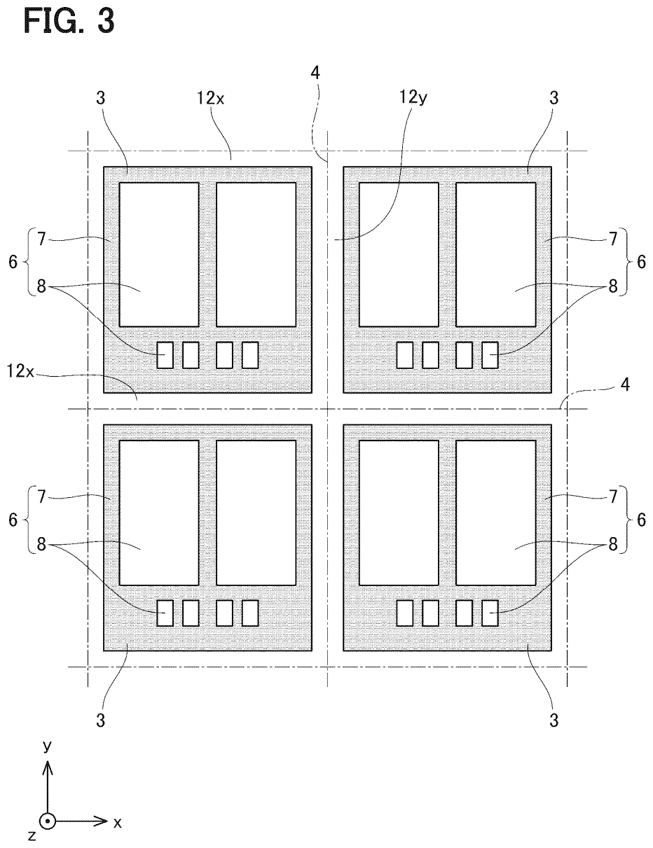

FIG. 3 is a schematic enlarged plan view showing four element regions 3 (four actual element regions 3A in this example) on the first main surface 2a of the semiconductor wafer 2. Each of the four element regions 3 includes a polyimide protective film 7 shown in gray, and aluminum electrode portions 8 surrounded by the protective film 7. The electrode portions 8 include a pair of main electrodes and signal electrodes for inputting and outputting gate signals and sensor signals. The protective film 7 and the electrode portion 8 constitute the pattern structure 6.

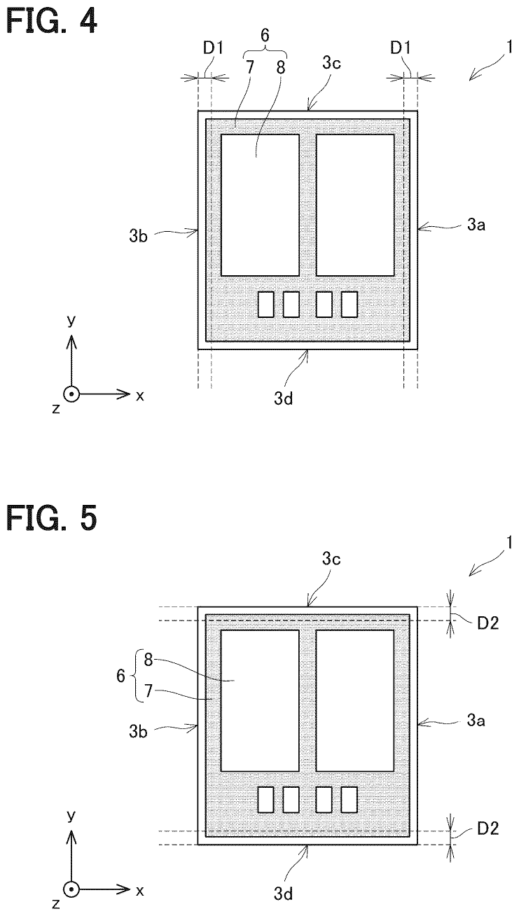

The relationship between the scribe lines 12 and the pattern structure 6 will be described. FIG. 4 and FIG. 5 show the semiconductor device 1 after being divided into individual pieces. Each of the semiconductor wafers 2 divided along the scribe lines 12 is called a semiconductor substrate. As will be explained in a manufacturing method described later, the semiconductor substrate of the semiconductor device 1 separated by a scribing and breaking method has four cleavage planes. A first side surface 3a and a second side surface 3b extend between the first main surface 2a and the second main surface 2b along the z-axis direction and are opposite to each other in the x-direction parallel to the first main surface 2a and the second main surface 2b. A third side surface 3c and a fourth side surface 3d extend between the first main surface 2a and the second main surface 2b along the z-axis direction and are opposite to each other in the y-axis direction parallel to the first main surface 2a and the second main surface 2b.

As shown in FIG. 4, a pattern structure within a first predetermined distance D1 from the first side surface 3a along the x-axis direction and a pattern structure within the first predetermined distance D1 from the second side surface 3b along the x-axis direction are symmetrical with respect to a line extending in the y-axis direction. In this example, the pattern structure present within the first predetermined distance D1 is only the polyimide protective film 7. Therefore, the structure of the protective film 7 within the first predetermined distance D1 from the first side surface 3a along the x-axis direction and the structure of the protective film 7 within the first predetermined distance D1 from the second side surface 3b along the x-axis direction are symmetrical with respect to the line extending in the y-axis direction. That is, the protective film 7 disposed within the first predetermined distance D1 from the first side surface 3a along the x-axis direction and the protective film 7 disposed within the first predetermined distance D1 from the second side surface 3b along the x-axis direction, that are disposed symmetrically with respect to the line extending in the y-axis direction, have the same height. The first predetermined distance D1 is defined as twice the width W2 of the second scribe line 12y of the semiconductor device 1 divided into individual pieces, as shown in FIG. 2A.

As shown in FIG. 5, a pattern structure within a second predetermined distance D2 from the third side surface 3c along the y-axis direction and a pattern structure within the second predetermined distance D2 from the fourth side surface 3d along the y-axis direction are symmetrical with respect to a line extending in the x-axis direction. In this example, the pattern structure present within the second predetermined distance D2 is only the polyimide protective film 7. Therefore, the structure of the protective film 7 within the second predetermined distance D2 from the third side surface 3c along the y-axis direction and the structure of the protective film 7 within the second predetermined distance D2 from the fourth side surface 3d along the y-axis direction are symmetrical with respect to the line extending in the x-axis direction. That is, the protective film 7 disposed within the second predetermined distance D2 from the third side surface 3c along the y-axis direction and the protective film 7 disposed within the second predetermined distance D2 from the fourth side surface 3d along the y-axis direction, that are disposed symmetrically with respect to the line extending in the x-axis direction, have the same height. The second predetermined distance D2 is defined as twice the width W1 of the first scribe line 12x as shown in FIG. 2B.

The pattern structures 6 of the respective actual element regions 3A in the semiconductor wafer 2 have the common shape. Therefore, when the above relationship is established, between the adjacent actual element regions 3A in the semiconductor wafer 2, the pattern structures 6 that oppose each other across the scribe line 12 are symmetrical with respect to the planned dividing line 4. The pattern structures 6 of the respective test element regions 3B may have the common shape with the pattern structures 6 of the actual element regions 3A within the predetermined distances D1 and D2. In this case, if the above relationship is established, between the adjacent actual element region 3A and test element region 3B in the semiconductor wafer 2, the pattern structures 6 that oppose each other across the scribe line 12 are symmetrical with respect to the planned dividing line 4. As will be described below, when the above relationship is established, the occurrence of chipping can be restricted when the semiconductor wafer 2 is divided into individual pieces.

### (Manufacturing Method of Semiconductor Device)

In a manufacturing method of the semiconductor device disclosed in the present specification, the element structure including the pattern structure 6 is formed in each of the element regions 3 in the semiconductor wafer 2, and then the semiconductor wafer 2 is divided into individual pieces using a scribing and breaking method to manufacture the semiconductor device 1. The scribing and breaking method will be described below with reference to the drawings.

### (Protective Tape Attaching Process and Crack Forming Process)

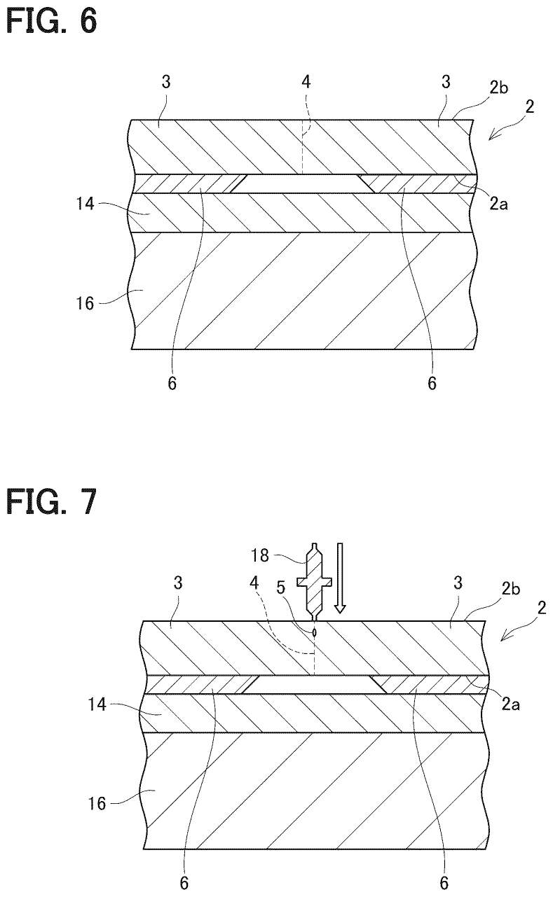

As shown in FIG. 6, in a protective tape application process, a protective tape 14 is attached to the first main surface 2a of the semiconductor wafer 2. The protective tape 14 is attached so as to straddle the surfaces of the pattern structures 6 respectively formed in the element regions 3 in the semiconductor wafer 2. The material of the protective tape 14 is not particularly limited, but may be, for example, a resin. Next, the semiconductor wafer 2 is placed on a stage 16 with the surface of the semiconductor wafer 2 to which the protective tape 14 is attached facing down. The stage 16 has a vacuum suction device (not shown), which is capable of suctioning and fixing the semiconductor wafer 2 to the stage 16.

Next, as shown in FIG. 7, in a crack forming process, a scribing wheel 18 is pressed against the second main surface 2b of the semiconductor wafer 2 to form a plurality of grooves accompanied by a plurality of cracks 5 in the semiconductor wafer 2. A metal electrode (not shown) may be formed on the entire surface of the second main surface 2b of the semiconductor wafer 2. In this case, the scribing wheel 18 is pressed against the second main surface 2b of the semiconductor wafer 2 via the metal electrode. The scribing wheel 18 is a disk-shaped member, and is rotatably supported by a support device (not shown). In the crack forming process, the scribing wheel 18 is moved along the planned dividing line 4 while being pressed against the second main surface 2b of the semiconductor wafer 2. The scribing wheel 18 rolls on the second main surface 2b of the semiconductor wafer 2 like a tire rolling on a road surface. The scribing wheel 18 is an example of a pressing member.

When the second main surface 2b of the semiconductor wafer 2 is pressed by the scribing wheel 18, a compressive stress is generated in a surface region of the second main surface 2b of the semiconductor wafer 2. While a groove is formed at a portion pressed by the scribing wheel 18, tensile stress is generated inside the semiconductor wafer 2 directly below the region where the compressive stress is generated. The tensile stress is generated in a direction away from the planned dividing lines 4 along the second surface 2b of the semiconductor wafer 2 directly below the region where the compressive stress is generated. Due to this tensile stress, the crack 5 extending in the thickness direction of the semiconductor wafer 2 is formed inside the semiconductor wafer 2. The crack 5 is formed in the vicinity of a surface layer of the second surface 2b of the semiconductor wafer 2.

### (Dividing Process)

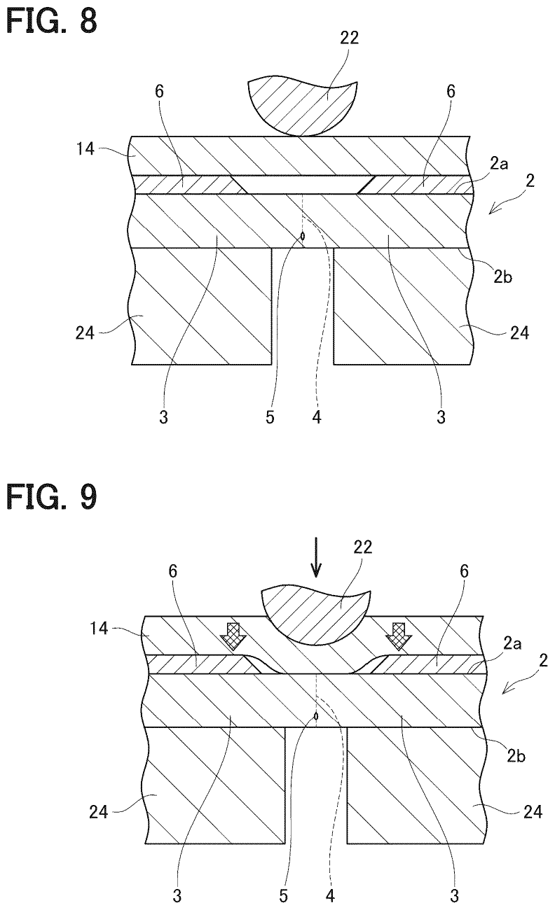

Next, a dividing process shown in FIGS. 8 to 10 is carried out. In FIGS. 8 to 10, the semiconductor wafer 2 is illustrated again with the first main surface 2a facing up. In the dividing process, a breaking bar 22 is pressed along the planned dividing line 4 to divide the semiconductor wafer 2 along the planned dividing line 4. First, as shown in FIG. 8, the semiconductor wafer 2 is placed on two support bases 24. The two support bases 24 are spaced apart from each other so as to have a gap therebetween. The semiconductor wafer 2 is placed on the support bases 24 so that the gap is located below the position where the semiconductor wafer 2 is to be divided, that is, the gap is located below the position where the breaking bar 22 is pressed against. Thereafter, as shown in FIG. 9, the breaking bar 22 is pressed against the first main surface 2a of the semiconductor wafer 2 via the protective tape 14. The breaking bar 22 is an example of a “dividing member”.

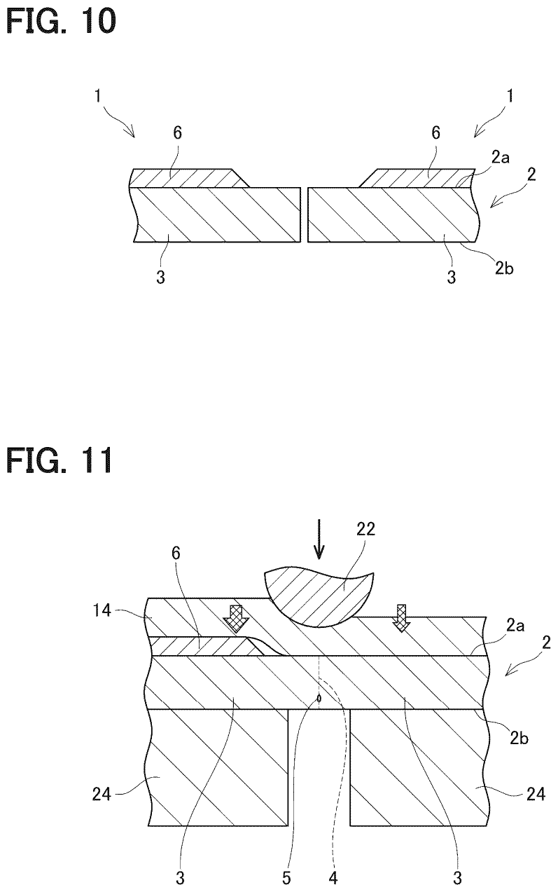

Since there is no support base 24 below the breaking bar 22, when the breaking bar 22 is pressed against the first main surface 2a of the semiconductor wafer 2 via the protective tape 14, the semiconductor wafer 2 bends so as to enter the space between the two support bases 24. In this case, the crack 5 has been formed in the vicinity of the second main surface 2b in the semiconductor wafer 2. Therefore, when the breaking bar 22 is pressed against the semiconductor wafer 2 in a direction facing the first main surface 2a, the semiconductor wafer 2 is bent about the pressed portion (line). Thus, in a region close to the second main surface 2b of the semiconductor wafer 2, a force is generated in directions separating the two element regions 3, which are adjacent across the crack 5 as a dividing position. As described above, the tensile stress is applied to the periphery of the crack 5. Therefore, when the breaking bar 22 is pressed against the first main surface 2a, the crack 5 extends in the thickness direction of the semiconductor wafer 2, and the semiconductor wafer 2 is cleaved along a crystal plane starting from the crack 5. As a result, the semiconductor wafer 2 is divided. In the dividing process, the above-mentioned process of pressing the breaking bar 22 against the first main surface 2a of the semiconductor wafer 2 is repeatedly carried out along each of the planned dividing lines 4. Accordingly, the semiconductor wafer 2 can be divided along the boundaries of the element regions 3. As a result, as shown in FIG. 10, the semiconductor wafer 2 is divided into a plurality of semiconductor devices 1.

As described above, the semiconductor device 1 is manufactured by forming the cracks 5 using the scribing wheel 18 and dividing the semiconductor wafer 2 using the breaking bar 22. Since the semiconductor wafer 2 is divided by cleavage starting from the cracks 5 rather than by cutting (dicing), this method is also useful for relatively hard silicon carbide. Furthermore, since the scribing and breaking method can narrow the scribe lines 12x, 12y, the number of the semiconductor devices 1 produced from the semiconductor wafer 2 can be increased, and a manufacturing cost can be reduced.

Now, with reference to FIG. 11, a dividing process of a comparative example will be described. This comparative example is an example in which the pattern structures 6 formed on the first main surfaces 2a of adjacent element regions 3 are asymmetrical. Specifically, the maximum height of the pattern structure 6 within a predetermined distance (see D1 and D2 in FIG. 2A and FIG. 2B) from the planned dividing line 4 is lower in the element region 3 on the right side of FIG. 11 than in the element region 3 on the left side of FIG. 11. In this comparative example, in the element region 3 on the right side of FIG. 11, no pattern structure is formed within a predetermined distance from the planned dividing line 4, and the height of the pattern structure 6 is “0”. As shown in FIG. 11, in the comparative example in which the pattern structures 6 are asymmetric, when the breaking bar 22 is pressed against the first main surface 2a of the semiconductor wafer 2 via the protective tape 14, a difference occurs in the load applied to each of the adjacent element regions 3 as shown by hatched arrows. A relatively large load is applied to the element region 3 having the higher maximum height of the pattern structure 6 located within a predetermined distance from the planned dividing line 4. Such a load difference can cause chipping in the element region 3 in which the maximum height of the pattern structure 6 is higher.

As shown in FIG. 2A and FIG. 2B, in the present embodiment, in the adjacent element regions 3, the pattern structures 6 within the predetermined distances D1 and D2 from the planned dividing line 4 are configured symmetrically with respect to the planned dividing line 4. Therefore, as shown by hatched arrows in FIG. 9, when the breaking bar 22 is pressed against the first main surface 2a of the semiconductor wafer 2 via the protective tape 14, a uniform load is applied to each of the adjacent element regions 3. As a result, in the dividing process of the present embodiment, the occurrence of chipping is restricted. In the present embodiment, the size of the predetermined distance D1 is twice the width W2 of the corresponding second scribe line 12y, and the size of the predetermined distance D2 is twice the width W1 of the corresponding first scribe line 12x. If the pattern structure 6 within the predetermined distances D1 and D2, which are twice the scribe line widths W1 and W2, is symmetrical, the load difference becomes sufficiently small, and the occurrence of chipping can be restricted. The range of the element region 3 to which the load is applied by the breaking bar 22 depends on a radius of curvature of a tip of the breaking bar 22, a thickness of the protective tape 14, and the amount of the breaking bar 22 pressed into the protective tape 14. Therefore, the predetermined distances D1 and D2 may be determined as “the radius of curvature of the tip of the breaking bar 22”+“the thickness of the protective tape 14”−“the amount of the breaking bar 22 pressed into the protective tape 14”.

Other features of technology described in the present specification will be summarized below.

In the manufacturing method disclosed in this specification, prior to the dividing process, the crack formation process is carried out in which the grooves and cracks 5 are formed in the semiconductor wafer 2 by pressing the scribing wheel 18 against the second main surface 2b of the semiconductor wafer 2. The stress generated inside the semiconductor wafer 2 when the grooves and cracks 5 are formed in the semiconductor wafer 2 remains as residual stress even after the semiconductor wafer 2 is divided. Therefore, in the semiconductor device 1 manufactured by the manufacturing method disclosed in the present specification, the residual stress in the second main surface 2b of the semiconductor substrate 2 is higher than the residual stress in the first main surface 2a. Even if such residual stress exists on the second main surface 2b of the semiconductor substrate 2, the influence on the electrical characteristics of the semiconductor device 1 is small. Incidentally, instead of forming the weakened portion including the grooves and the cracks 5 using the scribing wheel 18, a weakened portion may be formed by, for example, laser irradiation.

The pattern structures 6 in the actual element regions 3A are different from the pattern structures 6 in the test element regions 3B. Thus, in the comparative example, the pattern structures 6 within the predetermined distance D1, D2 in the actual element regions 3A are different from the pattern structures 6 within the predetermined distances D1, D2 in the test element region 3B, and the pattern structures 6 within the predetermined distance D1, D2 in the adjacent actual element regions 3A and test element regions 3B are asymmetric. In the technique disclosed in the present specification, the pattern structures 6 within the predetermined distances D1, D2 in the test element regions 3B are designed to be the same as the pattern structures 6 within the predetermined distances D1, D2 in the actual element regions 3A. As a result, the pattern structures 6 within the predetermined distances D1, D2 in the adjacent actual element region 3A and test element region 3B become symmetrical. Therefore, the occurrence of chipping can be restricted. The maximum height of the pattern structures 6 within the predetermined distances D1, D2 in the test element region 3B may be higher than the maximum height of the pattern structures 6 within the predetermined distances D1, D2 in the actual element region 3A adjacent to the test element region 3B. In this case, chipping occurs preferentially in the test element region 3B, so that chipping occurring in the actual element region 3A can be restricted.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor substrate having a first main surface, a second main surface opposite to the first main surface, and a side surface extending between the first main surface and the second main surface, the side surface being a cleavage plane and including a first side surface and a second side surface opposite to each other in a first direction parallel to the first main surface and the second main surface, and a third side surface and a fourth side surface opposite to each other in a second direction parallel to the first main surface and the second main surface and perpendicular to the first direction; and
a pattern structure having a protruding shape and disposed on the first main surface of the semiconductor substrate, wherein
the pattern structure within a first predetermined distance from the first side surface along the first direction and the pattern structure within the first predetermined distance from the second side surface along the first direction are symmetrical with respect to a line extending in the second direction, and
the pattern structure within a second predetermined distance from the third side surface along the second direction and the pattern structure within the second predetermined distance from the fourth side surface along the second direction are symmetrical with respect to a line extending in the first direction.

2. The semiconductor device according to claim 1, wherein
the first predetermined distance is twice a scribe line width that is measured from each of the first side surface and the second side surface to the pattern structure along the first direction, and
the second predetermined distance is twice a scribe line width that is measured from each of the third side surface and the fourth side surface to the pattern structure along the second direction.

3. The semiconductor device according to claim 1, wherein
the second main surface of the semiconductor substrate has a higher residual stress than the first main surface of the semiconductor substrate.

4. The semiconductor device according to claim 1, wherein
each of the pattern structure within the first predetermined distance from the first side surface along the first direction, the pattern structure within the first predetermined distance from the second side surface along the first direction, the pattern structure within the second predetermined distance from the third side surface along the second direction, and the pattern structure within the second predetermined distance from the fourth side surface along the second direction is a protective film.

5. The semiconductor device according to claim 1, wherein
the semiconductor substrate is made of silicon carbide.

6. A manufacturing method of a semiconductor device, comprising:
forming a pattern structure having a protruding shape on a first main surface of a semiconductor wafer that has the first main surface and a second main surface opposite to the first main surface, the forming of the pattern structure including forming the pattern structure in each of a plurality of element regions arranged in a matrix form in the semiconductor wafer; and
dividing the semiconductor wafer along a plurality of first scribe lines extending in a first direction parallel to the first main surface and the second main surface, and a plurality of second scribe lines extending in a second direction parallel to the first main surface and the second main surface and perpendicular to the first direction by pressing a dividing member against the plurality of first scribe lines and the plurality of second scribe lines to divide the semiconductor wafer into a plurality of semiconductor devices, wherein
each of the plurality of semiconductor devices includes a semiconductor substrate having a side surface extending between the first main surface and the second main surface, the side surface includes a first side surface and a second side surface opposed to each other in the first direction, and a third side surface and a fourth side surface opposed to each other in the second direction,
the pattern structure within a first predetermined distance from the first side surface along the first direction and the pattern structure within the first predetermined distance from the second side surface along the first direction are symmetrical with respect to a line extending in the second direction, and
the pattern structure within a second predetermined distance from the third side surface along the second direction and the pattern structure within the second predetermined distance from the fourth side surface along the second direction are symmetrical with respect to a line extending in the first direction.

7. The manufacturing method according to claim 6, wherein
the first predetermined distance is twice a scribe line width that is measured from each of the first side surface and the second side surface to the pattern structure along the first direction, and
the second predetermined distance is twice a scribe line width that is measured from each of the third side surface and the fourth side surface to the pattern structure along the second direction.

8. The manufacturing method according to claim 6, further comprising
forming a plurality of cracks in the semiconductor wafer by pressing a pressing member against the second main surface of the semiconductor wafer along each of the plurality of first scribe lines and each of the plurality of second scribe lines, prior to the dividing of the semiconductor wafer.

9. The manufacturing method according to claim 6, further comprising
attaching a protective tape to the first main surface of the semiconductor wafer prior to the dividing of the semiconductor wafer.

10. The manufacturing method according to claim 6, wherein
each of the pattern structure within the first predetermined distance from the first side surface along the first direction, the pattern structure within the first predetermined distance from the second side surface along the first direction, the pattern structure within the second predetermined distance from the third side surface along the second direction, and the pattern structure within the second predetermined distance from the fourth side surface along the second direction is a protective film.

11. The manufacturing method according to claim 6, wherein
the semiconductor wafer is made of silicon carbide.

12. The manufacturing method according to claim 6, wherein
the plurality of element regions in the semiconductor wafer includes an actual element region and a test element region, and
a height of the pattern structure within the first predetermined distance from each of the first side surface and the second side surface along the first direction and a height of the pattern structure within the second predetermined distance from each of the third side surface and the fourth side surface along the second direction in the test element region are respectively same as or higher than a height of the pattern structure within the first predetermined distance from each of the first side surface and the second side surface along the first direction and a height of the pattern structure within the second predetermined distance from each of the third side surface and the fourth side surface along the second direction in the actual element region that is adjacent to the test element region.
